(19) United States
(12) Patent Application Publication
(10) Pub. No.: US 2026/0068317 A1
(43) Pub. Date: Mar. 5, 2026

(54) SEMICONDUCTOR DEVICE AND METHOD OF FABRICATING THE SAME

(71) Applicant: Samsung Electronics Co., Ltd., Suwon-si (KR)

(72) Inventors: Seokhyeon Yoon, Suwon-si (KR); Seunghun Lee, Suwon-si (KR); Jeonghyeon Kim, Suwon-si (KR)

(21) Appl. No.: 19/226,324

(22) Filed: Jun. 3, 2025

(30) Foreign Application Priority Data
Aug. 28, 2024 (KR) 10-2024-0116081

(51) Int. Cl. H10D 84/90; H10D 89/10

(52) U.S. Cl. CPC H10D 84/991; H10D 84/953; H10D 89/10

(57) ABSTRACT

A semiconductor device may include a substrate including a first well region comprising an impurity of a first conductivity type, first active patterns on the first well region and spaced apart from each other in a first direction parallel to a top surface of the substrate, second active patterns on the first well region and spaced apart from each other in the first direction, source/drain patterns on the first active patterns, the source/drain patterns comprising an impurity of a second conductivity type, and first impurity patterns on the second active patterns, the first impurity patterns comprising an impurity of the first conductivity type. A width of a top surface of each of the second active patterns in the first direction may be greater than a width of a top surface of each of the first active patterns in the first direction.

### CROSS-REFERENCE TO RELATED APPLICATIONS

This U.S. non-provisional patent application claims priority under 35 U.S.C. § 119 to Korean Patent Application No. 10-2024-0116081, filed on Aug. 28, 2024, in the Korean Intellectual Property Office, the entire contents of which are hereby incorporated by reference.

### BACKGROUND OF THE INVENTION

The present disclosure relates to a semiconductor device and a method of fabricating the same, and in particular, to a semiconductor device including a field effect transistor and a method of fabricating the same.

A semiconductor device may include an integrated circuit including metal-oxide-semiconductor field-effect transistors (MOSFETs). To meet an increasing demand for a semiconductor device with a small pattern size and a reduced design rule, the MOSFETs are being aggressively scaled down. The scale-down of the MOSFETs may lead to deterioration in operational properties of the semiconductor device. A variety of studies are being conducted to overcome technical limitations associated with the scale-down of the semiconductor device and to realize high-performance semiconductor devices.

### SUMMARY OF THE INVENTION

Example embodiments of the inventive concepts provide a semiconductor device with improved electrical characteristics and a method of fabricating the same.

Example embodiments of the inventive concepts provide a semiconductor device with improved productivity and a method of fabricating the same.

According to some embodiments of the inventive concepts, a semiconductor device may include a substrate including a first well region comprising an impurity of a first conductivity type, first active patterns on the first well region and spaced apart from each other in a first direction parallel to a top surface of the substrate, second active patterns on the first well region and spaced apart from each other in the first direction, source/drain patterns on the first active patterns, the source/drain patterns comprising an impurity of a second conductivity type, and first impurity patterns on the second active patterns, the first impurity patterns comprising an impurity of the first conductivity type. A width of a top surface of each of the second active patterns in the first direction may be greater than a width of a top surface of each of the first active patterns in the first direction.

According to some embodiments of the inventive concepts, a semiconductor device may include a substrate including a first well region comprising an impurity of a first conductivity type, a first active pattern and a second active pattern on the first well region, a source/drain pattern on the first active pattern, the source/drain pattern comprising an impurity of a second conductivity type, and a first impurity pattern on the second active pattern, the first impurity pattern comprising an impurity of the first conductivity type. A first side surface of the second active pattern may protrude beyond a first side surface of the first active pattern in a first direction parallel to a top surface of the substrate.

According to some embodiments of the inventive concepts, a semiconductor device may include a substrate including a first well region comprising an impurity of a first conductivity type, first active patterns on the first well region and spaced apart from each other in a first direction parallel to a top surface of the substrate, second active patterns on the first well region and spaced apart from each other in the first direction, a division pattern between the first active patterns and the second active patterns, source/drain patterns on the first active patterns, the source/drain patterns comprising an impurity of a second conductivity type, first impurity patterns on the second active patterns, the first impurity patterns comprising an impurity of the first conductivity type, first semiconductor patterns on the first active patterns, second semiconductor patterns on the second active patterns, a gate electrode crossing at least one of the first semiconductor patterns, and active contacts on the source/drain patterns and the first impurity patterns. A width of a top surface of each of the second active patterns in the first direction may be greater than a width of a top surface of each of the first active patterns in the first direction.

### BRIEF DESCRIPTION OF THE DRAWINGS

FIGS. 1 and 2 are conceptual diagrams illustrating logic cells of a semiconductor device according to some embodiments of the inventive concepts.

FIG. 3 is a plan view illustrating a semiconductor device according to some embodiments of the inventive concepts.

FIG. 4 is an enlarged view illustrating a portion of FIG. 3.

FIG. 5A is a sectional view taken along a line A-A′ of FIG. 3.

FIG. 5B is a sectional view taken along a line B-B′ of FIG. 3.

FIG. 5C is a sectional view taken along a line C-C′ of FIG. 3.

FIG. 5D is a sectional view taken along a line D-D′ of FIG. 3.

FIGS. 6A, 6B, 6C, 6D, 7A, 7B, and 8 are diagrams illustrating a method of fabricating a semiconductor device, according to some embodiments of the inventive concepts.

### DETAILED DESCRIPTION

Example embodiments of the inventive concepts will now be described more fully with reference to the accompanying drawings, in which example embodiments are shown.

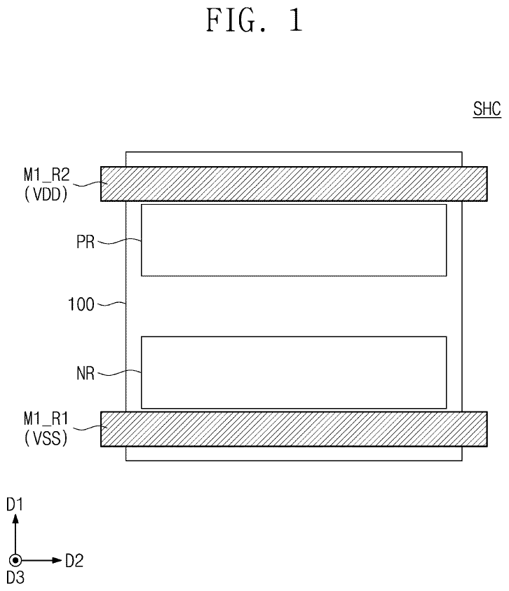

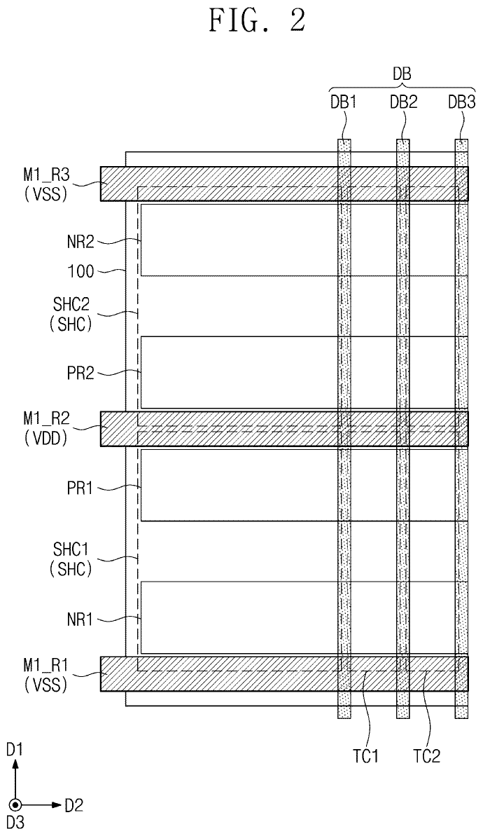

FIGS. 1 and 2 are conceptual diagrams illustrating logic cells of a semiconductor device according to some embodiments of the inventive concepts.

Referring to FIG. 1, a single height cell SHC may be provided on a substrate 100. In more detail, a first power line M1_R1 and a second power line M1_R2 may be provided on the substrate 100. The first power line M1_R1 may be a conduction path, to which a source voltage VSS (e.g., a ground voltage) is provided. The second power line M1_R2 may be a conduction path, to which a drain voltage VDD (e.g., a power voltage) is provided.

The single height cell SHC may be defined between the first power line M1_R1 and the second power line M1_R2. The single height cell SHC may include one PMOSFET region PR and one NMOSFET region NR. The PMOSFET region PR and the NMOSFET region NR may be spaced apart from each other in a first direction D1 and may be extended in a second direction D2. The first and second directions D1 and D2 may be parallel to a bottom and/or a top surface of the substrate 100 and may intersect each other. For example, the first and second directions D1 and D2 may be perpendicular to each other, but the present disclosure is not limited thereto.

The single height cell SHC may constitute a single logic cell. In the present specification, the logic cell may mean a logic device (e.g., AND, OR, XOR, XNOR, inverter, and so forth), which is configured to execute a specific function. In other words, the logic cell may include transistors constituting the logic device and interconnection lines connecting the transistors to each other.

Referring to FIG. 2, the single height cell SHC may include a first single height cell SHC1 and a second single height cell SHC2. The first single height cell SHC1 and the second single height cell SHC2 may be adjacent to each other in the first direction D1. The first single height cell SHC1 may be defined between the first power line M1_R1 and the second power line M1_R2. The second single height cell SHC2 may be defined between the second power line M1_R2 and a third power line M1_R3. The third power line M1_R3 may be a conduction path, to which the source voltage VSS is provided.

The first single height cell SHC1 may include one first PMOSFET region PR1 and one first NMOSFET region NR1. The second single height cell SHC2 may include one second PMOSFET region PR2 and one second NMOSFET region NR2. Although two single height cells SHC1 and SHC2 are illustrated in the drawings, the inventive concepts are not limited to this example.

The first PMOSFET region PR1 of the first single height cell SHC1 and the second PMOSFET region PR2 of the second single height cell SHC2 may be operated together as a single PMOSFET region. Although not shown, the first NMOSFET region NR1 of the first single height cell SHC1 and/or the second NMOSFET region NR2 of the second single height cell SHC2 may be operated as a single NMOSFET region in conjunction with an NMOSFET region of a neighboring single height cell.

A first tap cell TC1 and a second tap cell TC2 may be provided beside the single height cell SHC. The first tap cell TC1 may be interposed between the single height cell SHC and the second tap cell TC2. A first division pattern DB1 may be interposed between the single height cell SHC and the first tap cell TC1. A second division pattern DB2 may be interposed between the first and second tap cells TC1 and TC2. In some embodiments, a third division pattern DB3 may be provided beside the second tap cell TC2. In some other embodiments, the third division pattern DB3 may be omitted. The first to third division patterns DB1, DB2, and DB3 may constitute a division pattern DB. The active region of the single height cell SHC1 and/or SHC2 (e.g., the logic cell) may be electrically separated from the active region of the tap cell TC1 and/or TC2 by the division pattern DB.

Each of the first and second tap cells TC1 and TC2 may be used to apply a voltage from the power lines M1_R1 to M1_R3 to a well region of the substrate 100. FIG. 2 illustrates an example of the arrangement of the tap cells TC1 and TC2 and the logic cells SHC1 and SHC2, and the arrangement of the logic and tap cells may be variously changed by one of ordinary skill in the art.

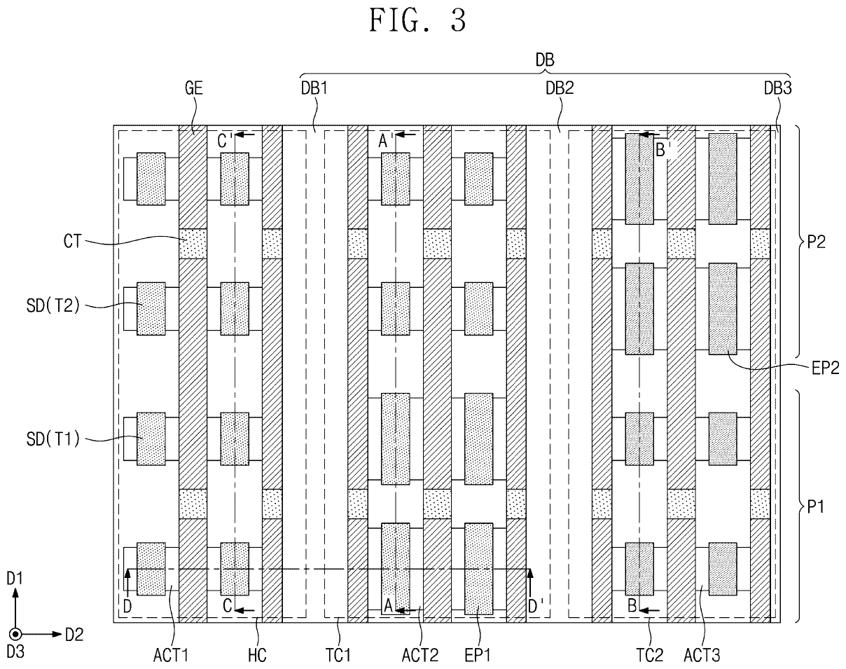

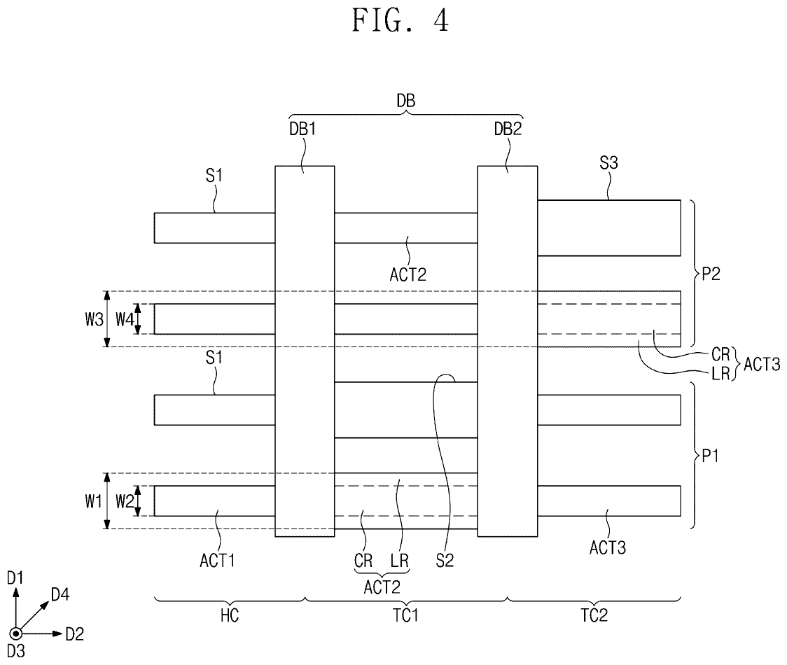

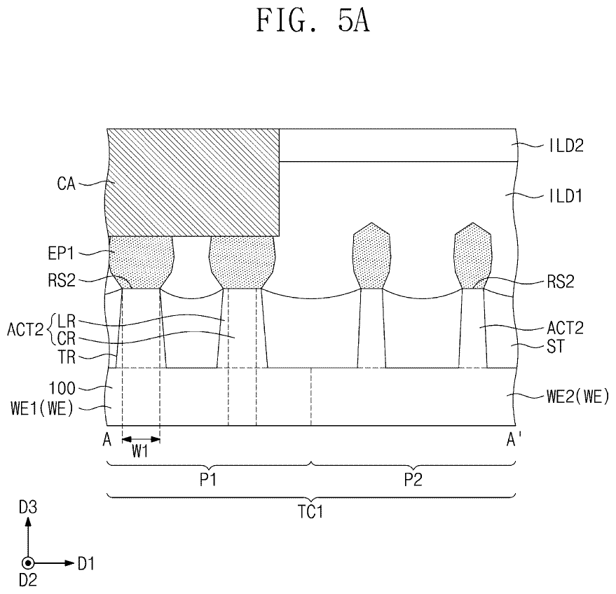

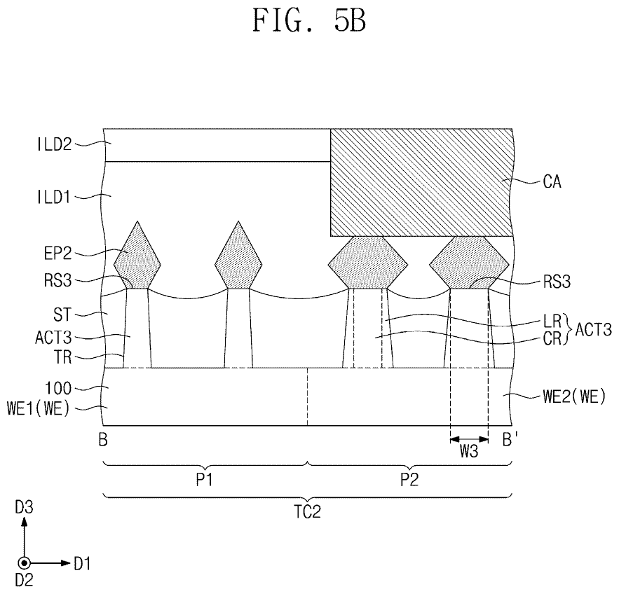

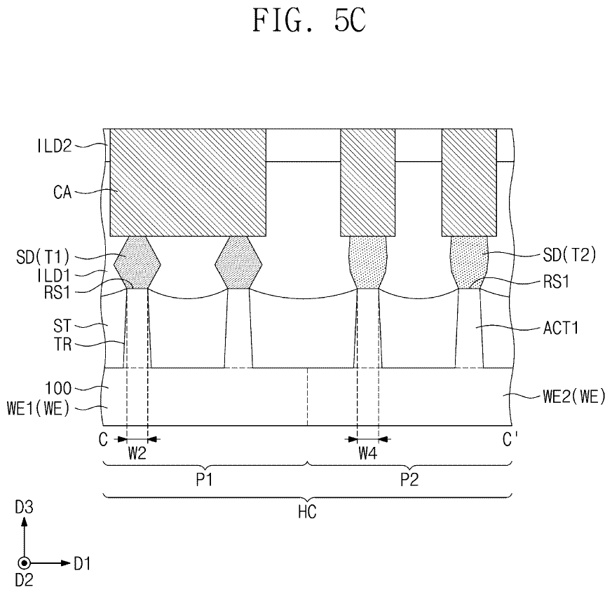

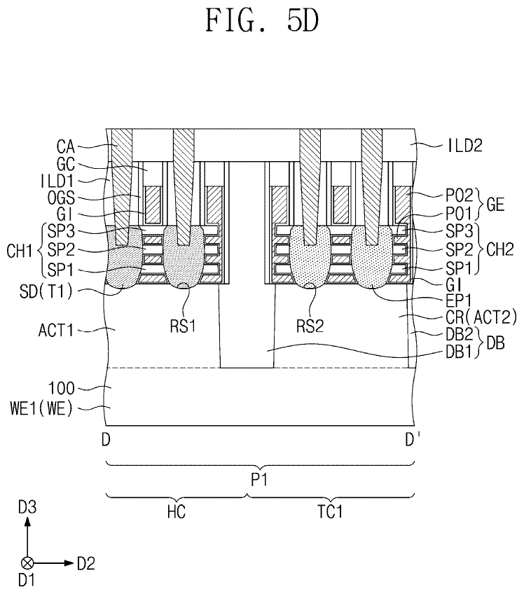

FIG. 3 is a plan view illustrating a semiconductor device according to some embodiments of the inventive concepts. FIG. 4 is an enlarged view illustrating a portion of FIG. 3. FIG. 5A is a sectional view taken along a line A-A′ of FIG. 3. FIG. 5B is a sectional view taken along a line B-B′ of FIG. 3. FIG. 5C is a sectional view taken along a line C-C′ of FIG. 3. FIG. 5D is a sectional view taken along a line D-D′ of FIG. 3.

Referring to FIGS. 3, 4, and 5A to 5D, the substrate 100 may be provided to include a first region P1 and a second region P2. In some embodiments, the substrate 100 may be a semiconductor substrate, which is formed of at least one of silicon, germanium, silicon germanium, or compound semiconductor materials. In the present specification, each of the expressions of “A or B”, “at least one of A and B”, “at least one of A or B”, “A, B, or C”, “at least one of A, B, and C”, and “at least one of A, B, or C” may be used to represent one of the elements enumerated in the expression or any possible combination of the enumerated elements.

The first region P1 may be a PMOSFET region. In detail, the first region P1 may include the first PMOSFET region PR1 and the second PMOSFET region PR2 described with reference to FIG. 2. The second region P2 may be an NMOSFET region. In some embodiments, the second region P2 may include the second NMOSFET region NR2 described with reference to FIG. 2 and an NMOSFET region of a neighboring single height cell.

The substrate 100 may include a height cell HC, a first tap cell TC1, and a second tap cell TC2. The height cell HC may mean the logic cell described with reference to FIGS. 1 and 2. The first tap cell TC1 may mean the first tap cell TC1 described with reference to FIG. 2. The second tap cell TC2 may mean the second tap cell TC2 described with reference to FIG. 2.

The substrate 100 may include a well region WE. The well region WE may contain at least one of impurities of first and second conductivity types. In some embodiments, the impurity of the first conductivity type may be an n-type impurity, and the impurity of the second conductivity type may be a p-type impurity. The well region WE may include a first well region WE1 on the first region P1 and a second well region WE2 on the second region P2.

The first and second well regions WE1 and WE2 may contain impurities of different conductivity types. In some embodiments, the first well region WE1 may contain impurities of the first conductivity type, and the second well region WE2 may contain impurities of the second conductivity type.

A bias voltage may be applied to the first well region WE1 in the first region P1 through elements, which are provided on the first tap cell TC1 and will be described below. A bias voltage may be applied to the second well region WE2 in the second region P2 through elements, which are provided on the second tap cell TC2 and will be described below.

Each of a first active pattern ACT1, a second active pattern ACT2, and a third active pattern ACT3 may be defined by a trench TR, which is formed in an upper portion of the substrate 100. A device isolation pattern ST including an insulating material may be formed to be in (e.g., to fill) the trench TR. Each of the first to third active patterns ACT1, ACT2, and ACT3 may be extended in the second direction D2, on the substrate 100. Each of the first to third active patterns ACT1, ACT2, and ACT3 may be a portion of the substrate 100. In some embodiments, the portion of the substrate 100 may protrude in a third direction D3. The third direction D3 may be perpendicular to a top surface of the substrate 100. In the present specification, for convenience of explanation, the substrate 100 may be referred to as the remaining portion of the substrate 100, excluding the first to third active patterns ACT1, ACT2, and ACT3, unless otherwise specified.

The first active pattern ACT1 may be provided on the height cell HC. In some embodiments, a plurality of first active patterns ACT1 may be provided. The first active patterns ACT1 may be spaced apart from each other in the first direction D1. In some embodiments, a pair of first active patterns ACT1, which are spaced apart from each other in the first direction D1, may be provided on the first region P1. A pair of first active patterns ACT1, which are spaced apart from each other in the first direction D1, may be provided on the second region P2.

The second active pattern ACT2 may be provided on the first tap cell TC1. In some embodiments, a plurality of second active patterns ACT2 may be provided. The second active patterns ACT2 may be spaced apart from each other in the first direction D1. In some embodiments, a pair of second active patterns ACT2, which are spaced apart from each other in the first direction D1, may be provided on the first region P1. The paired second active patterns ACT2 on the first region P1 may include extension portions LR and a center portion CR therebetween. A pair of second active patterns ACT2, which are spaced apart from each other in the first direction D1, may be provided on the second region P2.

The third active pattern ACT3 may be provided on the second tap cell TC2. In some embodiments, a plurality of third active patterns ACT3 may be provided. The third active patterns ACT3 may be spaced apart from each other in the first direction D1. In some embodiments, a pair of third active patterns ACT3, which are spaced apart from each other in the first direction D1, may be provided on the first region P1. A pair of third active patterns ACT3, which are spaced apart from each other in the first direction D1, may be provided on the second region P2. The paired third active patterns ACT3 on the second region P2 may include extension portions LR and a center portion CR therebetween.

The first and third active patterns ACT1 and ACT3 on the first region P1 may contain impurities (e.g., p-type impurities) of a different conductivity type from the first well region WE1. The second active patterns ACT2 on the first region P1 may contain impurities (e.g., n-type impurities) of the same conductivity type as the first well region WE1. The first and second active patterns ACT1 and ACT2 on the second region P2 may contain impurities (e.g., n-type impurities) of a different conductivity type from the second well region WE2. The third active patterns ACT3 on the second region P2 may contain impurities (e.g., p-type impurities) of the same conductivity type as the second well region WE2.

The first active patterns ACT1, the second active patterns ACT2, and the third active patterns ACT3 may be disposed to be spaced apart from each other in the second direction D2. The first active patterns ACT1 may be spaced apart from the second active patterns ACT2 with the division pattern DB interposed therebetween. The second active patterns ACT2 may be spaced apart from the third active patterns ACT3 with the division pattern DB interposed therebetween.

When measured in the first direction D1, a top surface of the second active pattern ACT2 on the first region P1 may have a first width W1. When measured in the first direction D1, a top surface of the first active pattern ACT1 on the first region P1 may have a second width W2. When measured in the first direction D1, a top surface of the third active pattern ACT3 on the second region P2 may have a third width W3. When measured in the first direction D1, a top surface of the first active pattern ACT1 on the second region P2 may have a fourth width W4.

The first width W1 may be larger than (i.e., may be greater than) the second width W2. The third width W3 may be larger than the fourth width W4. The second width W2 may be substantially equal to the fourth width W4. When measured in the first direction D1, the width of the third active pattern ACT3 on the first region P1 may be smaller than (i.e., may be less than) the first width W1 and may be substantially equal to the second width W2. When measured in the first direction D1, the width of the second active pattern ACT2 on the second region P2 may be smaller than the third width W3 and may be substantially equal to the fourth width W4.

In sum, the active pattern ACT2 on the first tap cell TC1 may have the largest width among the active patterns ACT1, ACT2, and ACT3 on the first region P1. The active pattern ACT3 on the second tap cell TC2 may have the largest width among the active patterns ACT1, ACT2, and ACT3 on the second region P2. The active pattern ACT2 on the first tap cell TC1 and the active pattern ACT3 on the second tap cell TC2 may be adjacent to each other in a fourth direction D4. Here, the fourth direction D4 may be parallel to the top surface of the substrate 100 and may be oblique to each of the first and second directions D1 and D2. An angle between the first and fourth directions D1 and D4 may be smaller than an angle between the first and second directions D1 and D2. That is, the fourth direction D4 may be a direction that is defined between or inclined to the first and second directions D1 and D2.

A distance between the second active patterns ACT2 on the first region P1 may be smaller than a distance between the first active patterns ACT1 on the first region P1 and a distance between the third active patterns ACT3 on the first region P1. For example, a distance in the first direction D1 between adjacent ones of the second active patterns ACT2 on the first region P1 may be less than a distance in the first direction D1 between adjacent ones of the first active patterns ACT1 on the first region P1 and a distance in the first direction D1 between adjacent ones of the third active patterns ACT3 on the first region P1. A distance between the third active patterns ACT3 on the second region P2 may be smaller than a distance between the first active patterns ACT1 on the second region P2 and a distance between the second active patterns ACT2 on the second region P2. For example, a distance in the first direction D1 between adjacent ones of the third active patterns ACT3 on the second region P2 may be less than a distance in the first direction D1 between adjacent ones of the first active patterns ACT1 on the second region P2 and a distance in the first direction D1 between adjacent ones of the second active patterns ACT2 on the second region P2.

The first active pattern ACT1 may have a first side surface S1, the second active pattern ACT2 may have a second side surface S2, and the third active pattern ACT3 may have a third side surface S3. Each of the first to third side surfaces S1, S2, and S3 may be faced in the first direction D1 and an opposite direction thereof. On the first region P1, the second side surface S2 may protrude in the first direction D1 and the opposite direction thereof, compared with each of the first and third side surfaces S1 and S3. On the second region P2, the third side surface S3 may protrude in the first direction D1 and the opposite direction thereof, compared with each of the first and second side surfaces S1 and S2. For example, the first active pattern ACT1, the second active pattern ACT2, and the third active pattern ACT3 on the first region P1 may be adjacent to each other in the second direction D2. On the first region P1, the second side surface S2 may be noncollinear along the second direction D2 with each of the first and third side surfaces S1 and S3. As another example, the first active pattern ACT1, the second active pattern ACT2, and the third active pattern ACT3 on the second region P2 may be adjacent to each other in the second direction D2. On the second region P2, the third side surface S3 may be noncollinear along the second direction D2 with each of the first and second side surfaces S1 and S2.

A first semiconductor pattern CH1 may be provided on the first active pattern ACT1. A second semiconductor pattern CH2 may be provided on the second active pattern ACT2. A third semiconductor pattern (not shown) may be provided on the third active pattern ACT3. In some embodiments, a plurality of first semiconductor patterns CH1, a plurality of second semiconductor patterns CH2, and a plurality of third semiconductor patterns may be provided. The first semiconductor patterns CH1 may be spaced apart from each other in the second direction D2, and the second semiconductor patterns CH2 and the third semiconductor patterns may be provided to have the same feature. Each of the first semiconductor patterns CH1, second semiconductor patterns CH2, and third semiconductor patterns may include a plurality of semiconductor layers SP1, SP2, and SP3, which are stacked in the third direction D3. For example, the semiconductor layers SP1, SP2, and SP3 may be spaced apart from each other in the third direction D3. FIG. 5D illustrates an example in which three semiconductor layers SP1, SP2, and SP3 are stacked, but the inventive concepts are not limited to this example; for example, four or more semiconductor layers may be provided in some embodiments. Each of the semiconductor layers SP1, SP2, and SP3 may include crystalline silicon.

Due to the aforementioned widths of the active patterns ACT1, ACT2, and ACT3, a width of the second semiconductor pattern CH2 on the first region P1 may be larger than a width of the first semiconductor pattern CH1 on the first region P1, when measured in the first direction D1. A width of the third semiconductor pattern on the second region P2 may be larger than a width of the first semiconductor pattern CH1 on the second region P2, when measured in the first direction D1.

A first recess RS1 may be defined between the first semiconductor patterns CH1. A second recess RS2 may be defined between the second semiconductor patterns CH2. A third recess RS3 may be defined between the third semiconductor patterns.

A source/drain pattern SD may be provided on the first active pattern ACT1 to be in (e.g., to fill) the first recess RS1. A first impurity pattern EP1 may be provided on the second active pattern ACT2 to be in (e.g., to fill) the second recess RS2. A second impurity pattern EP2 may be provided on the third active pattern ACT3 to be in (e.g., to fill) the third recess RS3. The source/drain pattern SD, the first impurity pattern EP1, and the second impurity pattern EP2 may be connected to the semiconductor layers SP1, SP2, and SP3.

The source/drain pattern SD may include a first pattern T1 on the first region P1 and a second pattern T2 on the second region P2.

In some embodiments, the first pattern T1 of the source/drain pattern SD and the second impurity pattern EP2 may include a semiconductor material (e.g., SiGe) having a lattice constant larger than that of the semiconductor material of the semiconductor layers SP1, SP2, and SP3. The second pattern T2 of the source/drain pattern SD and the first impurity pattern EP1 may include the same semiconductor material (e.g., Si) as the semiconductor layers SP1, SP2, and SP3.

The second pattern T2 of the source/drain pattern SD and the first impurity pattern EP1 may contain impurities (e.g., n-type impurities) of the same conductivity type as the first well region WE1. The first pattern T1 of the source/drain pattern SD and the second impurity pattern EP2 may contain impurities (e.g., p-type impurities) of the same conductivity type as the second well region WE2.

Due to the aforementioned widths of the active patterns ACT1, ACT2, and ACT3, the width of the first impurity pattern EP1 on the first region P1 may be larger than the width of the first pattern T1 of the source/drain pattern SD, when measured in the first direction D1. For example, the width of the first impurity pattern EP1 on the first region P1 may be larger than the width of the first impurity pattern EP1 on the second region P2, when measured in the first direction D1. The width of the second impurity pattern EP2 on the second region P2 may be larger than the width of the second pattern T2 of the source/drain pattern SD, when measured in the first direction D1. For example, the width of the second impurity pattern EP2 on the second region P2 may be larger than the width of the second impurity pattern EP2 on the first region P1, when measured in the first direction D1.

The distance between the first impurity patterns EP1 on the first region P1 may be smaller than the distance between the first patterns T1 of the source/drain pattern SD. For example, the distance in the first direction D1 between adjacent ones of the first impurity patterns EP1 on the first region P1 may be less than the distance in the first direction D1 between adjacent ones of the first patterns T1 of the source/drain pattern SD. The distance between the second impurity patterns EP2 on the second region P2 may be smaller than the distance between the second patterns T2 of the source/drain pattern SD. For example, the distance in the first direction D1 between adjacent ones of the second impurity patterns EP2 on the second region P2 may be less than the distance in the first direction D1 between adjacent ones of the second patterns T2 of the source/drain pattern SD.

A gate electrode GE may be provided on each of the first, second, and third semiconductor patterns (e.g., CH1 and CH2) to cross each semiconductor pattern. In some embodiments, a plurality of gate electrodes GE may be provided. The gate electrodes GE may be spaced apart from each other in the first and second directions D1 and D2.

The gate electrode GE may include an inner portion PO1 and an outer portion PO2. The inner portion PO1 may be provided below the uppermost one of the semiconductor layers SP1, SP2, and SP3. The outer portion PO2 may be provided on the uppermost one of the semiconductor layers SP1, SP2, and SP3. In some embodiments, the inner portion PO1 may include three inner portions, but the inventive concepts are not limited to this example. For example, the inner portion PO1 may include four or more inner portions.

The gate electrode GE may include a first metal pattern and a second metal pattern on the first metal pattern. In some embodiments, the first metal pattern may be formed of or include at least one of metallic materials (e.g., Ti, Mo, W, Cu, Al, Ta, Ru, Ir, and Co) and metal nitride materials (e.g., nitrides of Ti, Mo, W, Cu, Al, Ta, Ru, Ir, and Co). In some embodiments, the first metal pattern may further include carbon (C). The first metal pattern may be formed of or include at least one of metallic materials having different work functions.

In some embodiments, the second metal pattern may be formed of or include at least one of metallic materials (e.g., Ti, Mo, W, Cu, Al, Ta, Ru, Ir, and Co) whose electrical resistances are lower than that of the first metal pattern.

The inner portion PO1 may include the first metal pattern. The outer portion PO2 may include the first metal pattern and the second metal pattern.

A gate capping pattern GC may be provided on a top surface of the gate electrode GE. In some embodiments, the gate capping pattern GC may be formed of or include at least one of SION, SiCN, SiOCN, or SiN.

Outer gate spacers OGS may be provided on side surfaces of the outer portion PO2 of the gate electrode GE and may be respectively extended to be on (e.g., to cover and/or overlap) side surfaces of the gate capping pattern GC. As used herein, “an element A overlaps an element B in a direction X” (or similar language) means that there is at least one straight line that extends in the direction X and intersects both the elements A and B.

Inner gate spacers (not shown) may be interposed between the second pattern T2 of the source/drain pattern SD and the inner portion PO1 of the gate electrode GE and between the first impurity pattern EP1 and the inner portion PO1 of the gate electrode GE. In some embodiments, each of the outer gate spacer OGS and the inner gate spacer may include an insulating material.

A gate insulating pattern GI may be interposed between the gate electrode GE and the semiconductor layers SP1, SP2, and SP3. The gate insulating pattern GI may be formed of or include at least one of silicon oxide (SiO₂), silicon oxynitride (SiON), or high-k dielectric materials. In the present specification, the high-k dielectric material may be defined as a material having a higher dielectric constant than silicon oxide.

A cutting pattern CT may be provided between the gate electrodes GE, which are spaced apart from each other in the first direction D1. In some embodiments, the cutting pattern CT may include an insulating material.

The division pattern DB may be provided on the substrate 100. The division pattern DB may include the first division pattern DB1 between the height cell HC and the first tap cell TC1, the second division pattern DB2 between the first tap cell TC1 and the second tap cell TC2, and the third division pattern DB3 between the second tap cell TC2 and a neighboring logic cell. For example, the first division pattern DB1 may be between the first active patterns ACT1 and the second active patterns ACT2 (e.g., in the second direction D2). The second division pattern DB2 may be between the second active patterns ACT2 and the third active patterns ACT3 (e.g., in the second direction D2). In some embodiments, the division pattern DB may include an insulating material.

A first interlayer insulating layer ILD1 may be provided on the substrate 100. The first interlayer insulating layer ILD1 may be on (e.g., may cover and/or overlap) the outer gate spacers OGS, the source/drain patterns SD, the first impurity patterns EP1, and the second impurity patterns EP2.

A second interlayer insulating layer ILD2 may be provided on the first interlayer insulating layer ILD1. The second interlayer insulating layer ILD2 may be on (e.g., may cover and/or overlap) a top surface of the gate capping pattern GC. In some embodiments, each of the first and second interlayer insulating layers ILD1 and ILD2 may include silicon oxide (SiO₂).

An active contact CA may be provided to penetrate (i.e., extend into) the first and second interlayer insulating layers ILD1 and ILD2. A lower portion of the active contact CA may be inserted into an upper portion of each of the source/drain pattern SD and the first impurity pattern EP1, and the second impurity pattern EP2. In some embodiments, the active contact CA may be formed of or include at least one of metallic materials (e.g., Ti, Mo, W, Cu, Al, Ta, Ru, Ir, and Co), metal nitride materials (e.g., nitride materials containing Ti, Mo, W, Cu, Al, Ta, Ru, Ir, or Co), or metal silicide materials (e.g., silicide materials containing Ti, Mo, W, Cu, Al, Ta, Ru, or Ir).

A voltage applied to the active contact CA on the first tap cell TC1 may be delivered to the first well region WE1 through the first impurity pattern EP1 and the second active pattern ACT2. A voltage applied to the active contact CA on the second tap cell TC2 may be delivered to the second well region WE2 through the second impurity pattern EP2 and the third active pattern ACT3.

Gate contacts (not shown) may be provided to penetrate the gate capping pattern GC. Each of the gate contacts may be inserted into an upper portion of the outer portion PO2 of the gate electrode GE. In some embodiments, the gate contacts may be formed of or include at least one of metallic materials (e.g., Ti, Mo, W, Cu, Al, Ta, Ru, Ir, and Co) or metal nitride materials (e.g., nitride materials containing Ti, Mo, W, Cu, Al, Ta, Ru, Ir, or Co).

Although not shown, a plurality of interconnection layers may be further provided on the structure described above, and each of the interconnection layers may include interconnection patterns, which are formed of or include a conductive material. The interconnection patterns may be connected to the active contacts CA and the gate contacts (not shown).

At least one of the interconnection patterns may be used to apply a voltage to the first well region WE1 through the active contact CA, the first impurity pattern EP1, and the second active pattern ACT2 in the first tap cell TC1. At least one of the interconnection patterns may be used to apply a voltage to the second well region WE2 through the active contact CA, the second impurity pattern EP2, and the third active pattern ACT3 in the second tap cell TC2.

According to some embodiments of the inventive concepts, the width W1 of the top surface of the second active pattern ACT2 on the first well region WE1, which contains the n-type impurities, may be larger than the width W2 of the top surface of the first active pattern ACT1 on the first well region WE1. In addition, the width W3 of the top surface of the third active pattern ACT3 on the second well region WE2, which contains the p-type impurities, may be larger than the width W4 of the top surface of the first active pattern ACT1 on the second well region WE2. Thus, an overlap region between the second active pattern ACT2 and the first well region WE1 and an overlap region between the third active pattern ACT3 and the second well region WE2 may be increased. As a result, a resistance between the second active pattern ACT2 and the first well region WE1 and a resistance between the third active pattern ACT3 and the second well region WE2 may be reduced, when a voltage is applied to the well region WE through peripheral elements. Accordingly, it may be possible to suppress the latch-up phenomenon in a semiconductor device and to thereby improve the electrical characteristics of the semiconductor device.

Furthermore, the second active patterns ACT2, which include the extension portions LR in the first tap cell TC1, and the third active patterns ACT3, which include the extension portions LR in the second tap cell TC2, may be adjacent to each other in the fourth direction D4. In other words, the second and third active patterns ACT2 and ACT3 having large widths may be disposed in a diagonal direction. Accordingly, it may be possible to reduce a difficulty in placing and forming the active contacts CA and the interconnection patterns, which are connected to the second and third active patterns ACT2 and ACT3. This may make it possible to increase a degree of freedom in designing the semiconductor device.

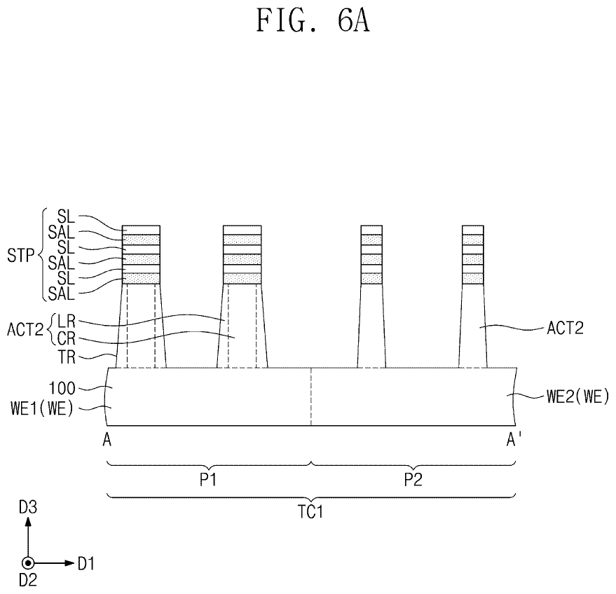

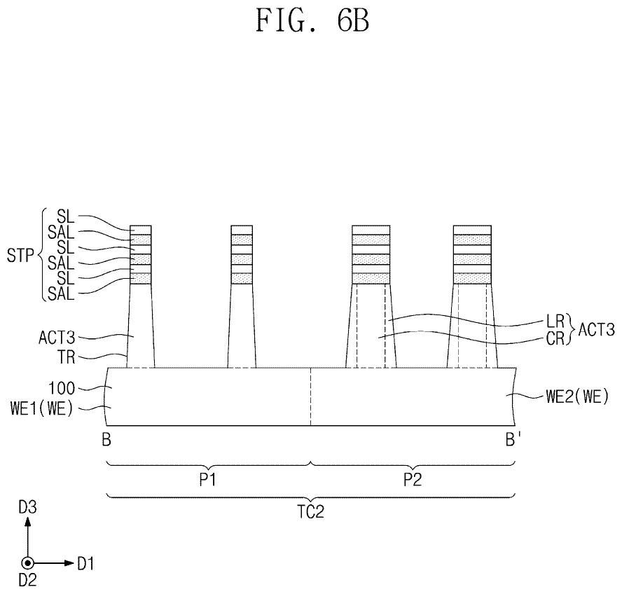

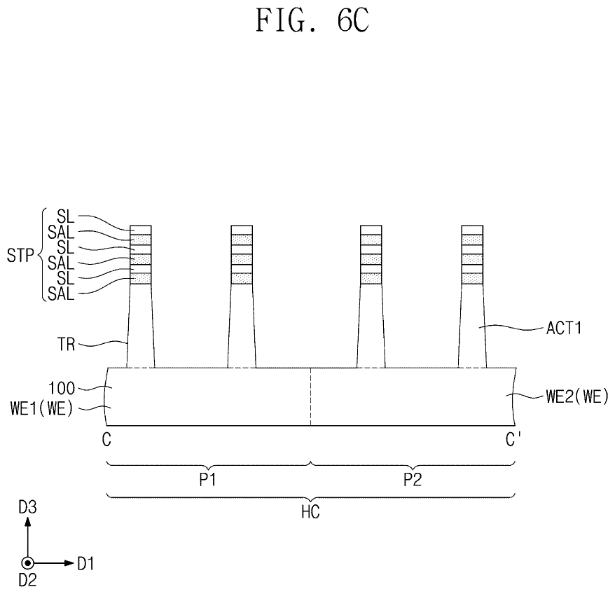

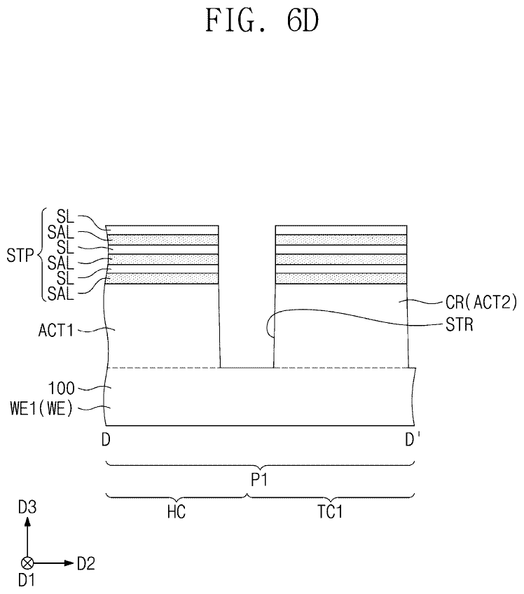

Hereinafter, a method of fabricating a semiconductor device according to some embodiments of the inventive concepts will be described with reference to FIGS. 6A, 6B, 6C, 6D, 7A, 7B, and 8. In the following description, a previously-described element may be identified by the same reference number without repeating an overlapping description thereof, for concise description.

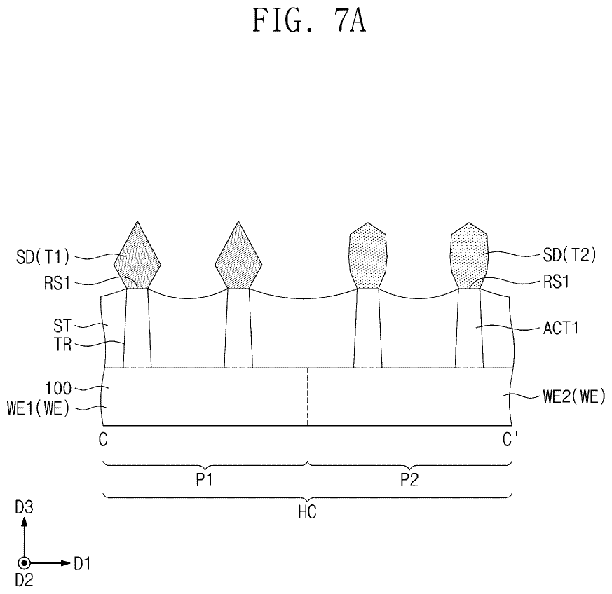

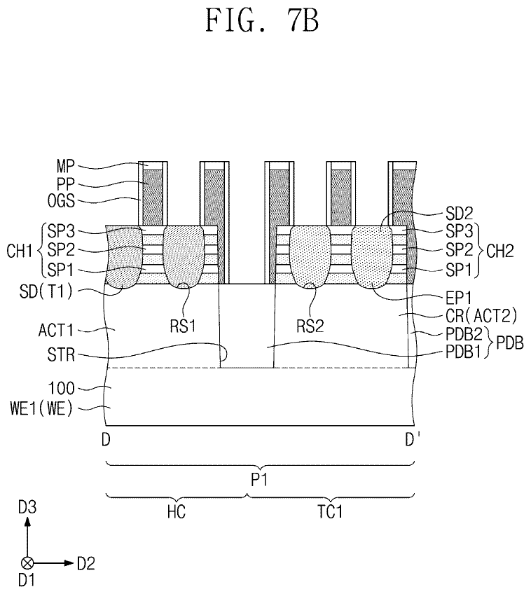

FIGS. 6A, 6B, 6C, 6D, 7A, 7B, and 8 are diagrams illustrating a method of fabricating a semiconductor device, according to some embodiments of the inventive concepts. In more detail, FIG. 6A is a sectional view taken along the line A-A′ of FIG. 3. FIG. 6B is a sectional view taken along the line B-B′ of FIG. 3. FIGS. 6C and 7A are sectional views taken along the line C-C′ of FIG. 3. FIGS. 6D, 7B, and 8 are sectional views taken along the line D-D′ of FIG. 3.

Referring to FIGS. 3 and 6A to 6D, the substrate 100 including the first and second well regions WE1 and WE2 may be provided.

A stacking pattern STP may be formed on the substrate 100. In some embodiments, the formation of the stacking pattern STP may include alternately stacking semiconductor layers SL and sacrificial layers SAL on the substrate 100, forming mask patterns (not shown) to extend in the second direction D2, and performing a first patterning process using the mask patterns as an etch mask. When the first patterning process is performed, a portion of the substrate 100 may be removed to form trenches TR.

In some embodiments, the active patterns ACT1, ACT2, and ACT3 may be formed to have different widths from each other, due to the first patterning process.

A second patterning process may be performed on the substrate 100 to form a separation trench STR. As a result of the first and second patterning processes, the first active patterns ACT1, the second active patterns ACT2, and the third active patterns ACT3, which are spaced apart from each other in the first and second directions D1 and D2, may be formed on the substrate 100.

The sacrificial layers SAL may include a material having an etch selectivity with respect to the semiconductor layers SL. Thus, the semiconductor layers SL may not be removed when the sacrificial layers SAL are removed in a subsequent step. The semiconductor and sacrificial layers SL and SAL may be formed of or include at least one of silicon (Si), germanium (Ge), or silicon germanium (SiGe), but the material of the sacrificial layers SAL may be different from that of the semiconductor layers SL.

Referring to FIGS. 3, 7A, and 7B, the device isolation patterns ST may be formed to be in (e.g., to fill) the trenches TR. A preliminary division pattern PDB may be formed to be in (e.g., to fill) the separation trench STR. The preliminary division pattern PDB may include a first preliminary division pattern PDB1, which is provided between the first active pattern ACT1 and the second active pattern ACT2, and a second preliminary division pattern PDB2, which is spaced apart from the first preliminary division pattern PDB1 with the second active pattern ACT2 interposed therebetween.

Sacrificial patterns PP may be formed on the substrate 100 to extend in the first direction D1. The sacrificial patterns PP may be formed to be on (e.g., to cover and/or overlap) the top surfaces of the device isolation patterns ST and the side and top surfaces of the stacking pattern STP. In some embodiments, the formation of the sacrificial patterns PP may include forming a sacrificial layer (not shown) on the substrate 100, forming hard mask patterns MP on the sacrificial layer, and forming the sacrificial patterns PP by removing a portion of the sacrificial layer using the hard mask patterns MP as an etch mask. In some embodiments, the sacrificial pattern PP may include polysilicon. Thereafter, the outer gate spacers OGS may be formed on side surfaces of the sacrificial patterns PP.

The first recesses RS1 may be formed in the stacking pattern STP on the first active pattern ACT1. The second recesses RS2 may be formed in the stacking pattern STP on the second active pattern ACT2. The third recesses RS3 of FIG. 5B may be formed in the stacking pattern STP on the third active pattern ACT3 of FIG. 6B. In some embodiments, the first to third recesses RS1, RS2, and RS3 may be formed by partially removing the stacking pattern STP using the hard mask patterns MP as an etch mask.

The semiconductor layers SL on the first active pattern ACT1 may be divided into the first semiconductor patterns CH1, which are spaced apart from each other in the second direction D2, by the first recesses RS1. The semiconductor layers SL on the second active pattern ACT2 may be divided into the second semiconductor patterns CH2, which are spaced apart from each other in the second direction D2, by the second recesses RS2. The semiconductor layers SL on the third active pattern ACT3 of FIG. 6B may be divided into the third semiconductor patterns, which are spaced apart from each other in the second direction D2, by the third recesses RS3 of FIG. 5B.

The source/drain patterns SD may be formed in the first recesses RS1. The first impurity patterns EP1 may be formed in the second recesses RS2. The second impurity patterns EP2 of FIG. 5B may be formed in the third recesses RS3 of FIG. 5B.

In some embodiments, when the first pattern T1 of the source/drain pattern SD and the second impurity pattern EP2 of FIG. 5B are formed, they may be doped with p-type impurities (e.g., boron, gallium, or indium) in an in-situ doping manner. In some other embodiments, the impurities may be injected into the first pattern T1 and the second impurity pattern EP2 (e.g., by an implantation process), after the formation of the first pattern T1 and the second impurity pattern EP2.

In some embodiments, when the second pattern T2 of the source/drain pattern SD and the first impurity pattern EP1 are formed, they may be doped with n-type impurities (e.g., phosphorus, arsenic or antimony) in an in-situ doping manner. In some other embodiments, the impurities may be injected into the second pattern T2 and the first impurity pattern EP1 (e.g., by an implantation process), after the formation of the second pattern T2 and the first impurity pattern EP1.

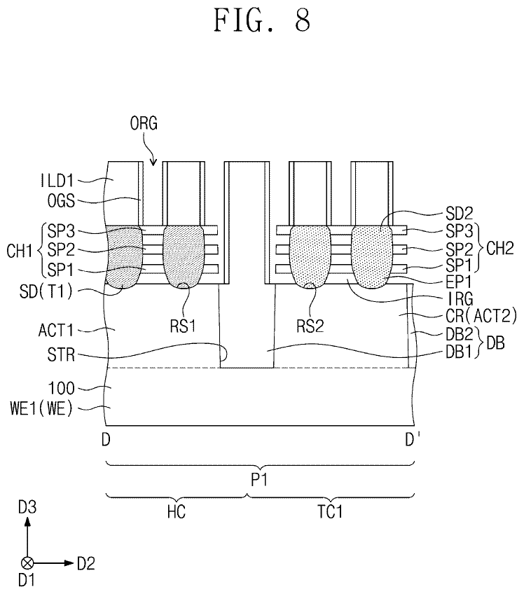

Referring to FIGS. 3 and 8, the first interlayer insulating layer ILD1 may be formed to be on (e.g., to cover and/or overlap) the source/drain patterns SD, the first impurity patterns EP1, the second impurity patterns EP2 of FIG. 5B, the hard mask patterns MP (see FIG. 7B), and the outer gate spacers OGS. Next, the first interlayer insulating layer ILD1 may be removed from the top surfaces of the sacrificial patterns PP (see FIG. 7B). In some embodiments, the removal process may be performed to remove the hard mask patterns MP and consequently to expose the sacrificial patterns PP. A portion of the first interlayer insulating layer ILD1 and the preliminary division pattern PDB may constitute the division pattern DB.

Thereafter, the exposed sacrificial patterns PP may be removed to form empty spaces, which will be referred to as outer regions ORG. The first semiconductor patterns CH1, the second semiconductor patterns CH2, the third semiconductor patterns, and the sacrificial layers SAL may be exposed to the outside through the outer region ORG.

Next, the exposed sacrificial layers SAL may be selectively removed. Here, the first to third semiconductor layers SP1, SP2, and SP3 may not be removed, due to the high etch selectivity of the sacrificial layers SAL.

Inner regions IRG may be empty spaces, which are formed by removing the sacrificial layers SAL. In more detail, the inner regions IRG may be formed between the first to third semiconductor layers SP1, SP2, and SP3.

According to some embodiments of the inventive concepts, the second active patterns ACT2 on the first region P1 may be spaced apart from each other, and the third active patterns ACT3 on the second region P2 may be spaced apart from each other. Thus, it may be possible to secure a space between the sacrificial layers SAL on the second active patterns ACT2 and a space between the sacrificial layers SAL on the third active patterns ACT3. As a result, it may be possible to easily remove the sacrificial layers SAL on the second and third active patterns ACT2 and ACT3 in a process of removing the sacrificial layers SAL. For example, the sacrificial layers SAL may not be left in a subsequent process, and this may make it possible to reduce a failure rate in a semiconductor fabrication process and to thereby increase the productivity of the semiconductor fabrication process.

Referring back to FIGS. 3 and 5A to 5D, the gate insulating pattern GI may be formed in each of the inner and outer regions IRG and ORG of FIG. 8. The gate insulating pattern GI may be formed to surround each of the first to third semiconductor layers SP1, SP2, and SP3.

The gate electrode GE may be formed on the gate insulating pattern GI. The gate capping pattern GC may be formed on the outer portion PO2 of the gate electrode GE. The second interlayer insulating layer ILD2 may be formed on the first interlayer insulating layer ILD1 and the gate capping pattern GC.

The active contacts CA may be formed to penetrate the first and second interlayer insulating layers ILD1 and ILD2. The active contacts CA may be formed to be connected to the source/drain pattern SD, the first impurity pattern EP1, and the second impurity pattern EP2.

The gate contacts (not shown) may be formed to penetrate the second interlayer insulating layer ILD2 and the gate capping pattern GC and may be connected to the gate electrodes GE.

Although not shown, additional interconnection patterns, which are formed of or include a conductive material, may be formed on the second interlayer insulating layer ILD2.

According to example embodiments of the inventive concepts, a width of a top surface of an active pattern may be larger on a tap cell than on a height cell. Thus, an overlap region between the active pattern on the tap cell and a well region, which contains n- or p-type impurities, may be increased. In this case, when the well region is applied with a voltage, a resistance between the active pattern on the tap cell and the well region may be lowered. Accordingly, it may be possible to suppress the latch-up phenomenon and to improve the electrical characteristics of the semiconductor device.

According to example embodiments of the inventive concepts, a pair of active patterns, which are spaced apart from each other, may be provided on the tap cell. Thus, it may be possible to secure a space between sacrificial layers on the active patterns. As a result, it may be possible to easily remove the sacrificial layers. For example, the sacrificial layers may not be left in a subsequent process, and this may make it possible to reduce a failure rate in a semiconductor fabrication process and to increase the productivity of the semiconductor fabrication process.

As used herein, the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof. In addition, it will be understood that, although the terms “first”, “second”, “third”, etc. may be used herein to describe various elements, these elements should not be limited by these terms. Rather, these terms are only used to distinguish one element from another. For example, a first element could be termed a second element, and, similarly, a second element could be termed a first element, without departing from the scope of the present disclosure. Further, as used herein, the term “and/or” includes any and all combinations of one or more of the associated listed items.

While example embodiments of the inventive concepts have been particularly shown and described, it will be understood by one of ordinary skill in the art that variations in form and detail may be made therein without departing from the scope of the attached claims.

What is claimed is:

1. A semiconductor device, comprising:
a substrate including a first well region comprising an impurity of a first conductivity type;
first active patterns on the first well region and spaced apart from each other in a first direction parallel to a top surface of the substrate;
second active patterns on the first well region and spaced apart from each other in the first direction;
source/drain patterns on the first active patterns, the source/drain patterns comprising an impurity of a second conductivity type; and
first impurity patterns on the second active patterns, the first impurity patterns comprising an impurity of the first conductivity type,
wherein a width of a top surface of each of the second active patterns in the first direction is greater than a width of a top surface of each of the first active patterns in the first direction.

2. The semiconductor device of claim 1, wherein the impurity of the first conductivity type is an n-type impurity, and
wherein the impurity of the second conductivity type is a p-type impurity.

3. The semiconductor device of claim 1, wherein a distance between adjacent ones of the second active patterns is less than a distance between adjacent ones of the first active patterns.

4. The semiconductor device of claim 1, wherein a distance between adjacent ones of the first impurity patterns is less than a distance between adjacent ones of the source/drain patterns.

5. The semiconductor device of claim 1, wherein a first one of the second active patterns is adjacent to a first one of the first active patterns in a second direction parallel to the top surface of the substrate and perpendicular to the first direction, and
wherein a side surface of the first one of the second active patterns protrudes in the first direction beyond a side surface of the first one of the first active patterns.

6. The semiconductor device of claim 1, wherein the substrate further includes a second well region adjacent to the first well region in the first direction and comprising an impurity of the second conductivity type,
wherein the semiconductor device further comprises:
a third active pattern on the second well region and spaced apart from the first active patterns in the first direction; and
a fourth active pattern on the second well region and spaced apart from the third active pattern in a second direction parallel to the top surface of the substrate and perpendicular to the first direction, and
wherein a width of a top surface of the fourth active pattern in the first direction is greater than a width of a top surface of the third active pattern in the first direction.

7. The semiconductor device of claim 6, wherein the source/drain patterns are first source/drain patterns, and
wherein the semiconductor device further comprises:
a second source/drain pattern on the third active pattern, the second source/drain pattern comprising an impurity of the first conductivity type; and
a second impurity pattern on the fourth active pattern, the second impurity pattern comprising an impurity of the second conductivity type.

8. The semiconductor device of claim 1, wherein the substrate further includes a second well region adjacent to the first well region in the first direction and comprising an impurity of the second conductivity type,
wherein the semiconductor device further comprises:
a third active pattern on the second well region and spaced apart from the second active patterns in the first direction; and
a fourth active pattern on the second well region and spaced apart from the third active pattern in a second direction parallel to the top surface of the substrate and perpendicular to the first direction, and
wherein a width of a top surface of the fourth active pattern in the first direction is greater than a width of a top surface of the third active pattern in the first direction.

9. The semiconductor device of claim 8, further comprising:
a second impurity pattern on the fourth active pattern, the second impurity pattern comprising an impurity of the second conductivity type; and
a third impurity pattern on the third active pattern, the third impurity pattern comprising an impurity of the first conductivity type.

10. The semiconductor device of claim 9, wherein a width of each of the first impurity patterns in the first direction is greater than a width of the third impurity pattern in the first direction.

11. The semiconductor device of claim 1, wherein a width of each of the first impurity patterns in the first direction is greater than a width of each of the source/drain patterns in the first direction.

12. The semiconductor device of claim 1, wherein each of the first active patterns comprises an impurity of the second conductivity type, and
wherein each of the second active patterns comprises an impurity of the first conductivity type.

13. A semiconductor device, comprising:
a substrate including a first well region comprising an impurity of a first conductivity type;
a first active pattern and a second active pattern on the first well region;
a source/drain pattern on the first active pattern, the source/drain pattern comprising an impurity of a second conductivity type; and
a first impurity pattern on the second active pattern, the first impurity pattern comprising an impurity of the first conductivity type,
wherein a first side surface of the second active pattern protrudes beyond a first side surface of the first active pattern in a first direction parallel to a top surface of the substrate.

14. The semiconductor device of claim 13, wherein a second side surface of the second active pattern opposite to the first side surface of the second active pattern protrudes beyond a second side surface of the first active pattern opposite to the first side surface of the first active pattern.

15. The semiconductor device of claim 13, wherein a width of a top surface of the second active pattern in the first direction is greater than a width of a top surface of the first active pattern in the first direction.

16. The semiconductor device of claim 13, wherein the first active pattern comprises a plurality of first active patterns that are on the first well region and are spaced apart from each other in the first direction,
wherein the second active pattern comprises a plurality of second active patterns that are on the first well region and are spaced apart from each other in the first direction, and
wherein a distance between adjacent ones of the second active patterns is less than a distance between adjacent ones of the first active patterns.

17. The semiconductor device of claim 16, wherein the first active patterns are spaced apart from the second active patterns in a second direction parallel to the top surface of the substrate and perpendicular to the first direction,
wherein each of the first active patterns comprises an impurity of the second conductivity type, and
wherein each of the second active patterns comprises an impurity of the first conductivity type.

18. The semiconductor device of claim 13, wherein the substrate further includes a second well region adjacent to the first well region in the first direction and comprising an impurity of the second conductivity type,
wherein the semiconductor device further comprises:
a third active pattern on the second well region and spaced apart from the first active pattern in the first direction; and
a fourth active pattern on the second well region and spaced apart from the third active pattern in a second direction parallel to the top surface of the substrate and perpendicular to the first direction, and
wherein a width of a top surface of the fourth active pattern in the first direction is greater than a width of a top surface of the third active pattern in the first direction.

19. The semiconductor device of claim 18, wherein the second active pattern and the fourth active pattern are spaced apart from each other in a third direction parallel to the top surface of the substrate and oblique to each of the first and second directions.

20. A semiconductor device, comprising:
a substrate including a first well region comprising an impurity of a first conductivity type;
first active patterns on the first well region and spaced apart from each other in a first direction parallel to a top surface of the substrate;
second active patterns on the first well region and spaced apart from each other in the first direction;
a division pattern between the first active patterns and the second active patterns;
source/drain patterns on the first active patterns, the source/drain patterns comprising an impurity of a second conductivity type;
first impurity patterns on the second active patterns, the first impurity patterns comprising an impurity of the first conductivity type;
first semiconductor patterns on the first active patterns;
second semiconductor patterns on the second active patterns;
a gate electrode crossing at least one of the first semiconductor patterns; and
active contacts on the source/drain patterns and the first impurity patterns, wherein a width of a top surface of each of the second active patterns in the first direction is greater than a width of a top surface of each of the first active patterns in the first direction.
